(19) United States
(12) Patent Application Publication
(10) Pub. No.: US 2026/0053074 A1
(43) Pub. Date: Feb. 19, 2026

(54) SEMICONDUCTOR PACKAGE

(71) Applicant: SAMSUNG ELECTRONICS CO., LTD., SUWON-SI (KR)

(72) Inventor: Minjung Kim, Suwon-si (KR)

(21) Appl. No.: 19/283,584

(22) Filed: Jul. 29, 2025

(30) Foreign Application Priority Data
Aug. 16, 2024 (KR) 10-2024-0110009

(51) Int. Cl. H01L 23/498; H01L 21/48; H01L 21/56; H01L 23/00; H01L 23/31; H01L 23/373; H01L 25/065; H01L 25/18; H10B 80/00; H10D 80/30

(52) U.S. Cl. CPC H01L 23/49816; H01L 21/4853; H01L 21/4857; H01L 21/565; H01L 23/3128; H01L 23/3135; H01L 23/373; H01L 23/49822; H01L 23/49833; H01L 25/0657; H01L 25/18; H01L 24/16; H01L 24/32; H01L 24/48; H01L 24/73; H01L 2224/16145; H01L 2224/16227; H01L 2224/32145; H01L 2224/32225; H01L 2224/48108; H01L 2224/48147; H01L 2224/73204; H01L 2224/73265; H01L 2225/06506; H01L 2225/0651; H01L 2225/06513; H01L 2225/06517; H01L 2225/06562; H01L 2225/06589; H01L 2924/1431; H01L 2924/1436; H10B 80/00; H10D 80/30

(57) ABSTRACT

A semiconductor package includes: a first redistribution structure; a first chip disposed on the first redistribution structure; a molding member at least partially surrounding the first chip and disposed on the first redistribution structure; a plurality of conductive pillars penetrating the molding member in a vertical direction; a support structure disposed between adjacent conductive pillars of the plurality of conductive pillars and disposed on the first redistribution structure; a second redistribution structure disposed on the molding member, the plurality of conductive pillars, and the support structure; a second chip disposed on the second redistribution structure and overlapping the plurality of conductive pillars; and a heat dissipation chip overlapping the first chip in the vertical direction.

### CROSS-REFERENCE TO RELATED APPLICATION

This application claims priority under 35 U.S. C. § 119 to Korean Patent Application No. 10-2024-0110009, filed on Aug. 16, 2024 in the Korean Intellectual Property Office, the disclosure of which is incorporated by reference herein in its entirety.

### TECHNICAL FIELD

The present inventive concept relates to a semiconductor package.

### DISCUSSION OF THE RELATED ART

Recently, the demand for portable devices in the electronic product market is rapidly increasing, thereby making it desirable for electronic components that are incorporated in electronic products to become smaller and lighter. For the electronic components to become smaller and lighter, it is desirable for semiconductor packages that are mounted on the electronic components to become smaller while processing larger amounts of data. As the semiconductor packages become smaller and lighter, studies for increasing the reliability of the semiconductor packages are ongoing.

### SUMMARY

According to an embodiment of the present inventive concept, a semiconductor package includes: a first redistribution structure; a first chip disposed on the first redistribution structure; a molding member at least partially surrounding the first chip and disposed on the first redistribution structure; a plurality of conductive pillars penetrating the molding member in a vertical direction; a support structure disposed between adjacent conductive pillars of the plurality of conductive pillars and disposed on the first redistribution structure; a second redistribution structure disposed on the molding member, the plurality of conductive pillars, and the support structure; a second chip disposed on the second redistribution structure and overlapping the plurality of conductive pillars; and a heat dissipation chip overlapping the first chip in the vertical direction.

According to an embodiment of the present inventive concept, a semiconductor package includes: a first redistribution structure; a first chip disposed on the first redistribution structure; a molding member at least partially surrounding the first chip and disposed on the first redistribution structure; a conductive pillar penetrating the molding member in a vertical direction; a support structure adjacent to the first chip in a first horizontal direction and disposed on the first redistribution structure, wherein the support structure is spaced apart from the conductive pillar; a second redistribution structure disposed on the molding member, the conductive pillar, and the support structure; and a second chip disposed on the second redistribution structure and overlapping at least a portion of the conductive pillar and at least a portion of the support structure, wherein a shape of an upper surface of the support structure is different from a shape of an upper surface of the conductive pillar.

According to an embodiment of the present inventive concept, a semiconductor package includes: a first redistribution structure; a first chip disposed on the first redistribution structure; a molding member sealing the first chip; a plurality of conductive pillars penetrating the molding member and arranged in a first horizontal direction and a second horizontal direction that is substantially perpendicular to the first horizontal direction in a plan view; a support structure disposed between adjacent conductive pillars of the plurality of conductive pillars with a predetermined distance from each of the adjacent conductive pillar and having a height equal to or less than a height of each of the plurality of conductive pillars; a second redistribution structure disposed on the molding member; a second chip disposed on the second redistribution structure and overlapping the plurality of conductive pillars and the support structure; and a heat dissipation chip overlapping the first chip, wherein the plurality of conductive pillars and the support structure are alternately disposed along a third direction that crosses the first horizontal direction and the second horizontal direction.

According to an embodiment of the present inventive concept, a method of manufacturing a semiconductor package includes: forming a first redistribution structure on a carrier substrate; mounting a first chip on the first redistribution structure; forming a plurality of conductive pillars and a plurality of support structures on the first redistribution structure, wherein the conductive pillars and support structures extend vertically from the first redistribution structure; forming a molding member on the first chip, the plurality of conductive pillars, and the plurality of support structures; planarizing an upper surface of the molding member such that the upper surfaces of the plurality of conductive pillars and the plurality of support structures are exposed; forming a second redistribution structure on the molding member and electrically connected to the conductive pillars; mounting a second chip on the second redistribution structure such that the second chip overlaps at least a portion of the plurality of conductive pillars and the plurality of support structures; and removing the carrier substrate and forming external connection terminals on a lower surface of the first redistribution structure.

In an embodiment of the present inventive concept, the plurality of support structures are formed to have a shape different from the plurality of conductive pillars in a plan view.

In an embodiment of the present inventive concept, the method further including disposing a heat dissipation chip on the second redistribution structure such that the heat dissipation chip overlaps the first chip.

In an embodiment of the present inventive concept, the support structures are disposed between adjacent conductive pillars.

### BRIEF DESCRIPTION OF THE DRAWINGS

The above and other aspects of the present inventive concept will become more apparent by describing in detail embodiments thereof, with reference to the accompanying drawings, in which:

FIG. 1 is a plan view of a semiconductor package according to an embodiment of the present inventive concept;

FIGS. 2A and 2B are cross-sectional views taken along line I-I′ of FIG. 1;

FIG. 3 is an enlarged view of region A of FIG. 1;

FIGS. 4A, 4B, and 4C are cross-sectional views illustrating the structure of a memory device of the semiconductor package of FIG. 2A or FIG. 2B;

FIGS. 5A and 5B are plan views of a semiconductor package according to an embodiment of the present inventive concept;

FIG. 6 is a cross-sectional view of a semiconductor package according to an embodiment of the present inventive concept;

FIGS. 7A, 7B and 7C are plan views of a semiconductor package according to an embodiment of the present inventive concept; and

FIGS. 8A, 8B, 8C, 8D, and 8E are cross-sectional views illustrating a method of manufacturing a semiconductor package, according to an embodiment of the present inventive concept.

### DETAILED DESCRIPTION OF THE EMBODIMENTS

Hereinafter, embodiments of the present inventive concept are described in detail with reference to the accompanying drawings. The same reference numerals are used for the same components in the drawings and specification, and redundant descriptions thereof are omitted. It is to be understood that the present inventive may be embodied in different forms and thus should not be construed as being limited to the embodiments set forth herein. In addition, the embodiments of the present inventive concept are not intended to limit the present inventive concept to the disclosed embodiments.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the spirit and scope of the present inventive concept.

As used herein, the singular forms “a,” “an,” and “the” are intended to include the plural forms as well, unless the context clearly indicates otherwise.

In the drawings, various thicknesses, lengths, and angles are shown and while the arrangement shown does indeed represent an embodiment of the present inventive concept, it is to be understood that modifications of the various thicknesses, lengths, and angles may be possible within the spirit and scope of the present inventive concept and the present inventive concept is not necessarily limited to the particular thicknesses, lengths, and angles shown.

Embodiments of the present inventive concept relate to a semiconductor package designed to address the challenges of reducing size and weight while increasing reliability, especially in portable electronic devices. The semiconductor package, according to embodiments of the present inventive concept, may include support structures and redistribution layers that may increase the semiconductor package's mechanical and electrical performance.

According to embodiments of the present inventive concept, the semiconductor package may include a first redistribution structure, on which a first chip is mounted. A molding member may surround the first chip to provide structural stability. The semiconductor package may further include conductive pillars that vertically penetrate the molding member and establish electrical connections between the redistribution layers. The conductive pillars may be complemented by support structures that may be placed between the conductive pillars to increase mechanical strength and mitigate warpage.

The semiconductor package may further include a second redistribution structure mounted on the molding member, on which a second chip is placed. The second chip may overlap the conductive pillars and support structures, ensuring efficient power and signal transmission while maintaining structural balance. The semiconductor package may further include a heat dissipation chip, which overlaps the first chip vertically, thereby increasing the thermal management of the semiconductor package.

Embodiments of the present inventive concept may be versatile, allowing for configurations such as stacked memory chips and high-bandwidth memory (HBM) packages. The support structures, which may have various shapes (e.g., star, diamond, or mesh), may improve warpage symmetry and ensure reliable connections under stress. Accordingly, a semiconductor package that has increased reliability, increased performance, and is mechanically robust may be provided.

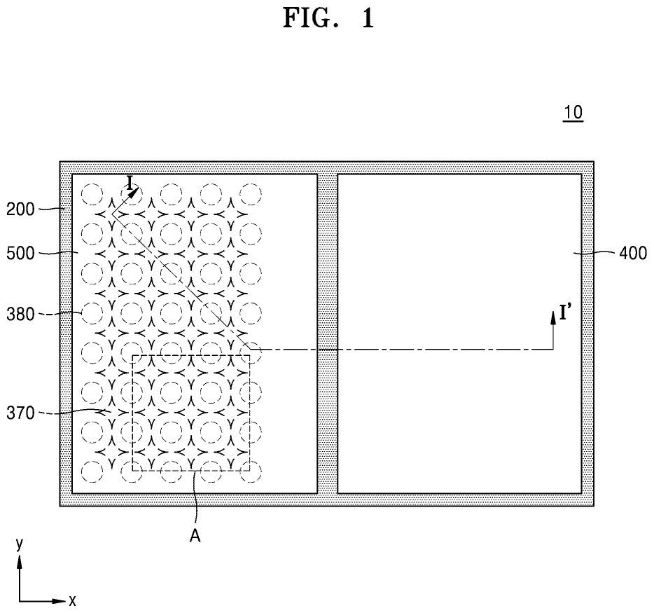

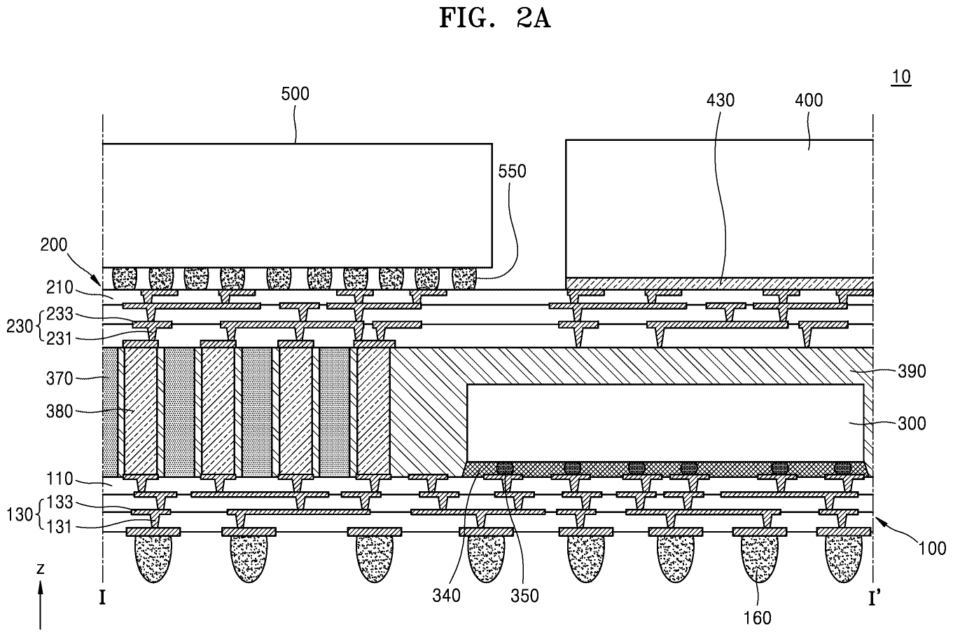

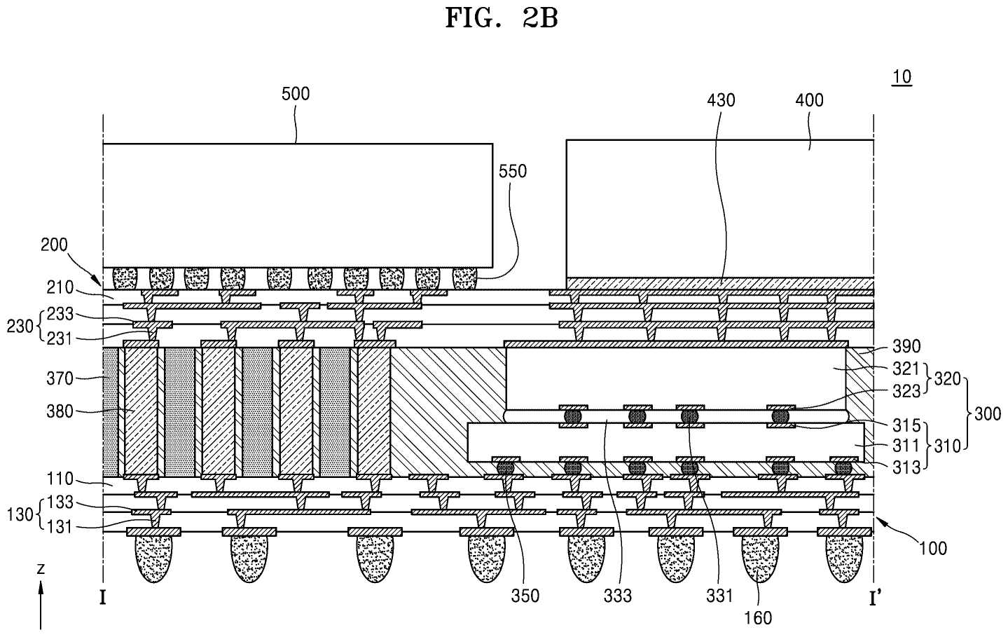

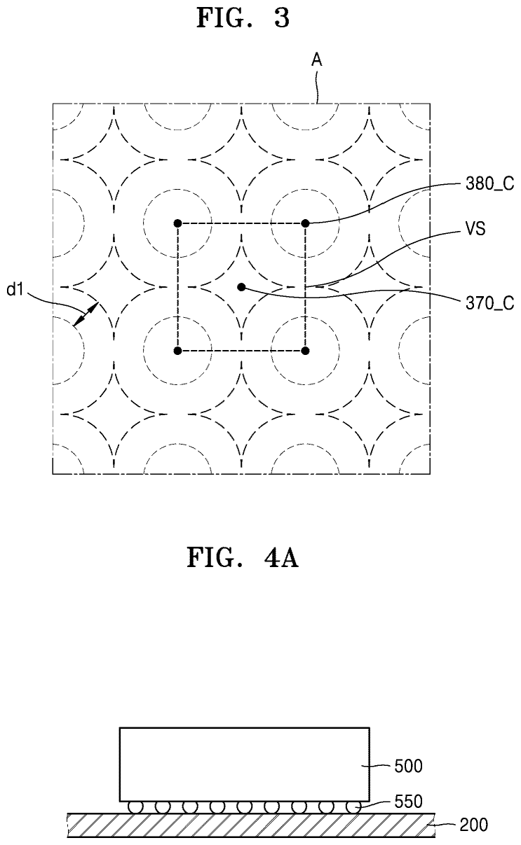

FIG. 1 is a plan view of a semiconductor package 10 according to an embodiment of the present inventive concept, FIGS. 2A and 2B are cross-sectional views of the semiconductor package 10 of FIG. 1 taken along line I-I′, and FIG. 3 is an enlarged view of region A of FIG. 1.

Referring to FIGS. 1 and 2A, the semiconductor package 10 according to an embodiment of the present inventive concept may include a first redistribution structure 100, a first chip 300, a molding member 390, a conductive pillar 380, a support structure 370, a second redistribution structure 200, a heat dissipation chip 400, and a second chip 500.

The first redistribution structure 100 may include opposite upper and lower surfaces, and at least one of the upper or lower surfaces may be a plane surface. The first redistribution structure 100 may be disposed below the first chip 300 and may electrically connect the first chip 300 to an external connection terminal 160 and may electrically connect the conductive pillar 380 to the external connection terminal 160. In an embodiment of the present inventive concept, the first redistribution structure 100 may electrically connect the support structure 370 to the external connection terminal 160.

The first redistribution structure 100 may include a first redistribution insulating layer 110 and a first redistribution pattern 130. The first redistribution insulating layer 110 may include a plurality of layers stacked on each other in one direction, and the first redistribution pattern 130 may be disposed in the stacked insulating layers.

In the drawings, the direction in which the plurality of first redistribution insulating layers 110 are stacked may be understood as a Z-axis direction, and an X-axis direction and a Y-axis direction may be understood as being perpendicular to each other on a plane having the Z-axis direction as a normal vector. That is, the X-axis direction and the Y-axis direction may be parallel to the upper or lower surface of the first redistribution structure 100, and the X-axis direction and the Y-axis direction may be perpendicular to each other. In other words, the Z-axis direction may be perpendicular to an X-Y plane in a direction perpendicular to the upper or lower surface of the first redistribution structure 100. In addition, a first horizontal direction, a second horizontal direction, and a vertical direction in the drawings may be understood as described below. The first horizontal direction may be understood as the X-axis direction. The second horizontal direction may be understood as the Y-axis direction, and the vertical direction may be understood as the Z-axis direction.

The first redistribution insulating layer 110 may be formed from, for example, photo imageable dielectric (PID) or photosensitive polyimide (PSPI).

The first redistribution pattern 130 may include metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or the like, or alloys thereof, but the present inventive concept is not limited thereto. In some embodiments of the present inventive concept, the first redistribution pattern 130 may be formed by laminating metal or alloys thereof on a seed layer including Cu, Ti, TiN, or TiW.

The first redistribution pattern 130 may include a first redistribution line pattern 133 and a first redistribution via pattern 131. The first redistribution line pattern 133 may extend in the first horizontal direction (the X-axis direction) and the first redistribution via pattern 131 may extend in the vertical direction (the Z-axis direction). The first redistribution pattern 130 may have a multilayer structure in which the first redistribution line pattern 133 and the first redistribution via pattern 131 are alternately stacked on each other. The first redistribution pattern 133 may extend in the horizontal direction with respect to at least one of the upper and lower surfaces of each of the first redistribution insulating layer 110. The first redistribution via pattern 131 may penetrate and extend through the first redistribution insulating layer 110 in the vertical direction (the Z-axis direction). The first redistribution via pattern 131 may physically connect the first redistribution line patterns 133, which are located at different levels in the vertical direction (the Z-axis direction), to each other.

In some embodiments of the present inventive concept, at least some of the first redistribution line patterns 133 may be formed integrally together with some of the first redistribution via patterns 131. In some embodiments of the present inventive concept, the first redistribution via pattern 131 may have a tapered shape of which the width decreases as the vertical level decreases (e.g., as the vertical level approaches the lower surface of the first redistribution structure 100). However, the shape of the first redistribution via pattern 131 is not limited thereto, and the first redistribution via pattern 131 may have a horizontal width that increases as the vertical level decreases or a horizontal width that is constant regardless of the vertical level. The first redistribution pattern 130 may be physically connected to the conductive pillar 380 and the first chip 300. In an embodiment of the present inventive concept, the first redistribution pattern 130 may be physically connected to the support structure 370. In an embodiment of the present inventive concept, the support structure 370 may contact the first redistribution insulating layer 110.

In some embodiments of the present inventive concept, the first redistribution structure 100 may include a printed circuit board (PCB). In this case, for example, the first redistribution insulating layer 110 may include at least one of phenol resin, epoxy resin, and/or polyimide. The first redistribution insulating layer 110 may include at least one material of, for example, flame retardant 4 (FR-4), tetrafunctional epoxy, polyphenylene ether, epoxy/polyphenylene oxide, bismaleimide triazine (BT), thermount, cyanate ester, polyimide, and/or liquid crystal polymer. In addition, for example, the first redistribution pattern 130 may include Cu, Ni, stainless steel, and/or beryllium copper.

The external connection terminal 160 may be disposed below the first redistribution structure 100. The external connection terminal 160 may be electrically connected to the first redistribution structure 100. The external connection terminal 160 may be physically connected to an external device, for example, to a motherboard. The external connection terminal 160 may be physically connected to the first redistribution pattern 130. The external connection terminal 160 may transmit an electrical signal that is received from the first chip 300, the heat dissipation chip 400, and/or the second chip 500 through the first redistribution pattern 130 to an external device or transmit an electrical signal received from the external device to the first chip 300, the heat dissipation chip 400, and/or the second chip 500 through the first redistribution pattern 130. The external connection terminal 160 may include a conductive material, for example, at least one of solder, Sn, Ag, Cu, and/or Al.

The first chip 300 may be mounted on the upper surface of the first redistribution structure 100. The first chip 300 may be electrically connected to the first redistribution pattern 130. In some embodiments of the present inventive concept, the first chip 300 may be mounted on the first redistribution structure 100 with a flip-chip method. For example, the first chip 300 may be mounted on the first redistribution structure 100 through a first bump 350 with the flip-chip method.

In some embodiments of the present inventive concept, the first bump 350 and a first underfill material layer 340 surrounding the first bump 350 may be disposed between the first chip 300 and the first redistribution structure 100. The first underfill material layer 340 may fix the first bump 350. The first underfill material layer 340 may include an epoxy resin formed by a capillary under-fill method, for example. In addition, in some embodiments of the present inventive concept, the molding member 390 may fill a gap between the first chip 300 and the first redistribution structure 100 through a molded under-fill process. In this case, the first underfill material layer 340 may be omitted.

In some embodiments of the present inventive concept, the first chip 300 may generate more heat than the second chip 500. The first chip 300 may include a logic chip. The logic chip may include, for example, microprocessors such as a central processing unit (CPU), a graphics processing unit (GPU), or an application processor (AP), an analog device, or a digital signal processor.

However, the first chip 300 is not limited thereto, and the first chip 300 may include a memory chip. The memory chip may include, for example, a volatile memory chip, such as dynamic random access memory (DRAM) or static random access memory (SRAM), or a non-volatile memory semiconductor chip, such as phase-change random access memory (PRAM), magnetoresistive random access memory (MRAM), ferroelectric random access memory (FeRAM), or resistive random access memory (RRAM).

The molding member 390 may at least partially surround the first chip 300 and may be disposed on the upper surface of the first redistribution structure 100. In some embodiments of the present inventive concept, the molding member 390 may surround the side surface and the upper surface of the first chip 300. The molding member 390 may be formed from a thermosetting resin such as epoxy resin, a thermoplastic resin such as polyimide, or a resin containing reinforcement such as inorganic fillers, particularly ajinomoto build-up film (ABF), FR-4, and BT, but embodiments of the present inventive concept are not limited thereto, and the molding member 390 may be formed from a molding material such as an epoxy mold compound (EMC) or a photosensitive material such as photoimageable encapsulant (PIE). In some embodiments of the present inventive concept, a portion of the molding member 390 may include an insulating material such as a silicon oxide layer, a silicon nitride layer, or a silicon oxynitride layer.

The conductive pillar 380 may be spaced apart from the first chip 300 in the horizontal direction and may be disposed on the upper surface of the first redistribution structure 100. In some embodiments of the present inventive concept, a plurality of conductive pillars 380 may be provided. The plurality of conductive pillars 380 may be spaced apart from each other in the horizontal direction. For example, as shown in FIG. 1, the plurality of conductive pillars 380 may be arranged along the first horizontal direction (the X-axis direction) and the second horizontal direction (the Y-axis direction). The conductive pillar 380 may extend in the vertical direction (the Z-axis direction) and may penetrate the molding member 390 in the vertical direction (the Z-axis direction).

The conductive pillar 380 may electrically connect the second redistribution structure 200 to the first redistribution structure 100. For example, the conductive pillar 380 may be a vertical connection conductor electrically connecting the first redistribution structure 100 to the second redistribution structure 200. In some embodiments of the present inventive concept, the upper surface of each of the plurality of conductive pillar 380 may be on substantially the same plane as the upper surface of the molding member 390.

The conductive pillar 380 may include, for example, Cu. However, the material of the conductive pillar 380 is not limited to Cu. For example, the conductive pillar 380 may be formed through electroplating using a seed metal. Accordingly, the conductive pillar 380 may be referred to as a Cu-post. The seed metal may include various metal materials such as Cu, Ti, Ta, TiN, TaN, and the like. In the semiconductor package 10 according to an embodiment of the present inventive concept, the seed metal may be included as a portion of the conductive pillar 380. For example, the seed metal and the conductive pillar 380 may both be formed of Cu. Accordingly, in FIG. 2A, the seed metal is not shown separately.

The semiconductor package 10 according to some embodiments of the present inventive concept may include the support structure 370, thereby improving warpage symmetry and joint reliability of the semiconductor package 10. In addition, the support structure 370 may help to distribute mechanical stress more evenly across the semiconductor package 10, reducing the likelihood of deformation or failure during operation. Additionally, the support structure 370 may increase the overall durability and performance consistency of the package in various environmental conditions.

The support structure 370 may be spaced apart from the first chip 300 in the horizontal direction and may be disposed on the upper surface of the first redistribution structure 100. In some embodiments of the present inventive concept, the support structure 370 may extend in the vertical direction (the Z-axis direction) and may penetrate the molding member 390 in the vertical direction (the Z-axis direction). The upper surface of the support structure 370, the upper surface of the conductive pillar 380, and the upper surface of the molding member 390 may be at substantially the same vertical level. In an embodiment of the present inventive concept, the support structure 370 may be spaced apart from the conductive pillar 380, and the molding member 390 may be disposed between the support structure 370 and the conductive pillar 380.

In some embodiments of the present inventive concept, a plurality of support structures 370 may be provided. For example, as shown in FIG. 2A, the plurality of support structures 370 may be arranged along the first horizontal direction (the X-axis direction) and the second horizontal direction (the Y-axis direction). The support structure 370 may be disposed between conductive pillars 380 that are adjacent to each other. The support structure 370 may be spaced apart by a predetermined distance from the conductive pillar 380 adjacent thereto. The support structures 370 and the conductive pillars 380 may be alternately disposed in a third direction (e.g., a diagonal direction) crossing the first horizontal direction (the X-axis direction) and the second horizontal direction (the Y-axis direction).

Referring to FIG. 3, in a plan view, the shape of the support structure 370 may be different from the shape of the conductive pillar 380. The shape of the upper surface of the support structure 370 may be different from the shape of the upper surface of the conductive pillar 380. The support structure 370 may be spaced apart by a predetermined distance dl from the conductive pillar 380 adjacent thereto. The support structure 370 has four edges, and each edge may be spaced apart by a predetermined distance from an edge of the conductive pillar 380 adjacent to the support structure 370. For example, as shown in FIG. 1, the conductive pillar 380 is circular and the support structure 370 may be an approximately star shape (or a commendation shape), from a plan view. For example, the support structure 370 may have four curved sides that protrude toward an inner region of the support structure 370 and that are connected to each other. However, various embodiments of the present inventive concept are not limited thereto. For example, the shape of the support structure 370 may be diamond, an oval, or a polygon.

In some embodiments of the present inventive concept, a center 370_C of the support structure 370 may be the same as a center of a virtual square VS (or, e.g., rectangle) formed by connecting centers 380_C of four adjacent conductive pillars 380 that surround the support structure 370. For example, this arrangement may increase structural support, electrical performance, and warpage reduction within the semiconductor package.

The support structure 370 may include, for example, Cu. However, the material of the support structure 370 is not limited to Cu. The support structure 370 may be formed through electroplating using a seed metal. The seed metal may include various metal materials such as Cu, Ti, Ta, TiN, TaN, and the like. In the semiconductor package 10 according to an embodiment of the present inventive concept, the seed metal may be included as a portion of the support structure 370. For example, the seed metal and the support structure 370 may both be formed of Cu. Accordingly, in FIG. 2A, the seed metal is not shown separately.

Referring to FIG. 2A, the second redistribution structure 200 may be disposed on the upper surface of the molding member 390. The second redistribution structure 200 may include opposite upper and lower surfaces, and at least one of the upper or lower surfaces may be a plane surface. The second chip 500 and the heat dissipation chip 400 may be disposed on the second redistribution structure 200, and the second chip 500 may be spaced apart from heat dissipation chip 400 in the first horizontal direction (the X-axis direction) by a predetermined distance. According to some embodiments of the present inventive concept, the second redistribution structure 200 may overlap the heat dissipation chip 400 in the vertical direction (the Z-axis direction).

The second redistribution structure 200 may electrically connect the conductive pillar 380 to the second chip 500. The second redistribution structure 200 may include a second redistribution insulating layer 210 and a second redistribution pattern 230. The second redistribution structure 200 may electrically connect the conductive pillar 380 to the second chip 500 through the second redistribution pattern 230. The second redistribution insulating layer 210 may include a plurality of layers stacked in the vertical direction (the Z-axis direction). The second redistribution pattern 230 may include a second redistribution via pattern 231 and a second redistribution pattern 233.

Since the second redistribution insulating layer 210 and the second redistribution pattern 230 are substantially and respectively the same as or similar to the first redistribution insulating layer 110 and the first redistribution pattern 130 described above, repeated descriptions thereof are omitted.

The heat dissipation chip 400 may be spaced apart from the second chip 500 in the first horizontal direction (the X-axis direction) and may be disposed on the upper surface of the molding member 390. The heat dissipation chip 400 may overlap the first chip 300 in the vertical direction (the Z-axis direction). Accordingly, the heat dissipation characteristics of the semiconductor package 10 may be improved. A thermal interfacial material (TIM) layer 430 may be disposed between the heat dissipation chip 400 and the second redistribution structure 200. The TIM layer 430 may fix the heat dissipation chip 400 to the upper surface of the second redistribution structure 200. For example, the second redistribution structure 200 may be disposed between the heat dissipation chip 400 and the molding member 390. In some embodiments of the present inventive concept, the TIM layer 430 may include an insulating material or a material that may maintain electrical insulation by including an insulating material. The TIM layer 430 may include, for example, an insulating base layer such as an epoxy resin and a heat dissipation filler contained in the insulating base layer. The TIM layer 430 may include, for example, mineral oil, grease, gap filler putty, phase change gel, phase change material pads, or particle filled epoxy.

In some embodiments of the present inventive concept, the heat dissipation chip 400 may include silicon (Si) as a dummy chip. The heat dissipation chip 400 may include a material having a high heat conductivity. In some embodiments of the present inventive concept, the vertical level of the upper surface of the heat dissipation chip 400 may be substantially the same as the vertical level of the upper surface of the second chip 500.

The second chip 500 may be disposed on the upper surface of the second redistribution structure 200 and be apart from the heat dissipation chip 400 in the first horizontal direction (the X-axis direction). The second chip 500 may overlap the conductive pillar 380 and the support structure 370 in the vertical direction (the Z-axis direction).

In some embodiments of the present inventive concept, the second chip 500 may include a memory chip. The memory chip may include a volatile memory chip, such as DRAM or SRAM, or a non-volatile memory semiconductor chip, such as PRAM, MRAM, FeRAM, or RRAM. The second chip 500 may be mounted on the second redistribution structure 200 through a second bump 550 with a flip-chip method. In some embodiments of the present inventive concept, an underfill material layer at least partially surrounding the second bump 550 may be disposed between the second chip 500 and the second redistribution structure 200. In some embodiments of the present inventive concept, the second chip 500 may receive a power signal from an external device through the second redistribution pattern 230 that is connected to the conductive pillar 380.

Referring to FIG. 2B, the first chip 300 may have a three-dimensional (3D) stack structure including a plurality of semiconductor chips stacked onto each other in the vertical direction (the Z-axis direction). For example, the first chip 300 may include a lower semiconductor chip 310 and an upper semiconductor chip 320 disposed on the lower semiconductor chip 310.

The lower semiconductor chip 310 may include a lower semiconductor substrate 311, a lower connection pad 313 disposed below the lower semiconductor substrate 311 and in contact with the first bump 350, and an upper connection pad 315 disposed above the lower semiconductor substrate 311. The lower semiconductor chip 310 may further include through electrodes penetrating the lower semiconductor substrate 311 and electrically connecting the lower connection pad 313 to the upper connection pad 315.

The upper semiconductor chip 320 may include an upper semiconductor substrate 321 and a lower connection pad 323 disposed below the upper semiconductor substrate 321. The upper connection pad 315 of the lower semiconductor chip 310 may be electrically and physically connected to the lower connection pad 323 of the upper semiconductor chip 320 through an inter-chips connection bump 331. A gap-fill insulating layer 333 at least partially surrounding the side wall of the inter-chips connection bump 331 may be disposed between the lower semiconductor chip 310 and the upper semiconductor chip 320. The gap-fill insulating layer 333 may be formed, for example, from a non-conductive film (NCF).

Each of the lower semiconductor substrate 311 and the upper semiconductor substrate 321 may be formed from a semiconductor wafer. The lower semiconductor substrate 311 and the upper semiconductor substrate 321 may include, for example, Si. In addition, the lower semiconductor substrate 311 and the upper semiconductor substrate 321 may include semiconductor elements such as germanium (Ge), or compound semiconductors such as silicon carbide (SiC), gallium arsenide (GaAs), indium arsenide (InAs), and indium phosphide (InP). The lower semiconductor substrate 311 and the upper semiconductor substrate 321 may include a conductive area, such as a well doped with impurities or a structure doped with impurities. The lower semiconductor chip 310 may include a semiconductor device layer provided in and/or on the active surface of the lower semiconductor substrate 311 (e.g., the lower surface of the lower semiconductor substrate 311), and the upper semiconductor chip 320 may include a semiconductor device layer provided in and/or on the active surface of the upper semiconductor substrate 321 (e.g., the lower surface of the upper semiconductor substrate 321). The semiconductor device layer of the lower semiconductor chip 310 and the semiconductor device layer of the upper semiconductor chip 320 may each include individual devices. The individual devices may include, for example, a transistor. The individual devices may include microelectronic devices, for example, a metal-oxide-semiconductor field effect transistor (MOSFET), an image sensor such as a system large scale integration (LSI) and a complementary metal-oxide semiconductor (CMOS) image sensor (CIS), a micro-electro-mechanical system (MEMS), an active device, a passive device, and the like.

In an embodiment of the present inventive concept, the first chip 300 may include three or more semiconductor chips stacked on each other in the vertical direction (the Z-axis direction) or may consist of a single semiconductor chip.

Referring to FIG. 2B, in an embodiment of the present inventive concept, the molding member 390 might not cover the upper surface of the first chip 300. The upper surface of the first chip 300 may be the upper surface of the upper semiconductor chip 320. In an embodiment of the present inventive concept, the upper surface of the molding member 390 may be on substantially the same plane as the upper surface of the first chip 300. For example, the second redistribution structure 200 may be disposed on the upper semiconductor chip 320. Referring to FIG. 2B, the upper surface of the first chip 300 may be in direct contact with the second redistribution structure 200. The second redistribution pattern 233 between the first chip 300 and the heat dissipation chip 400 may have a generally parallel plate form.

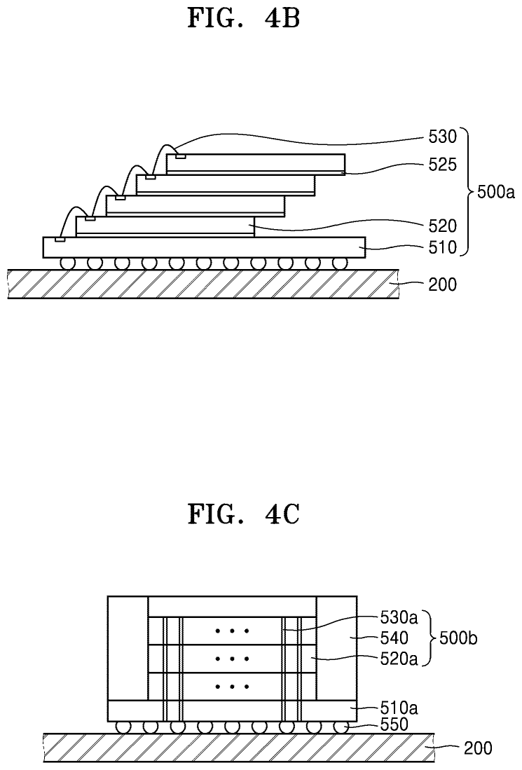

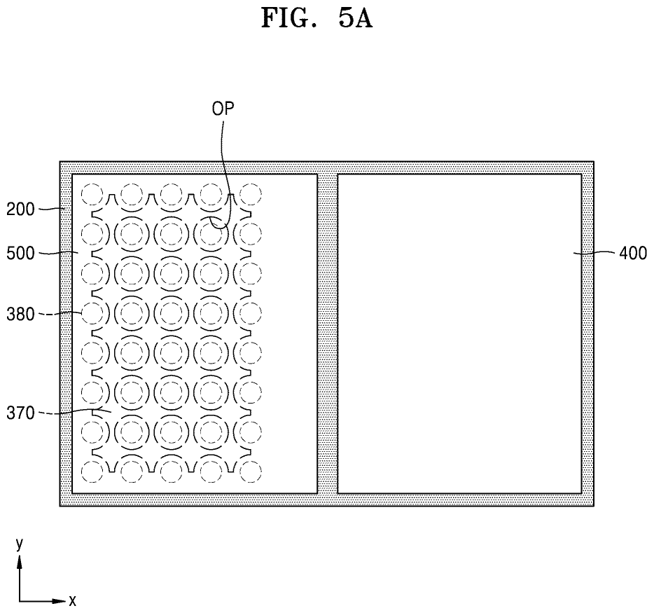

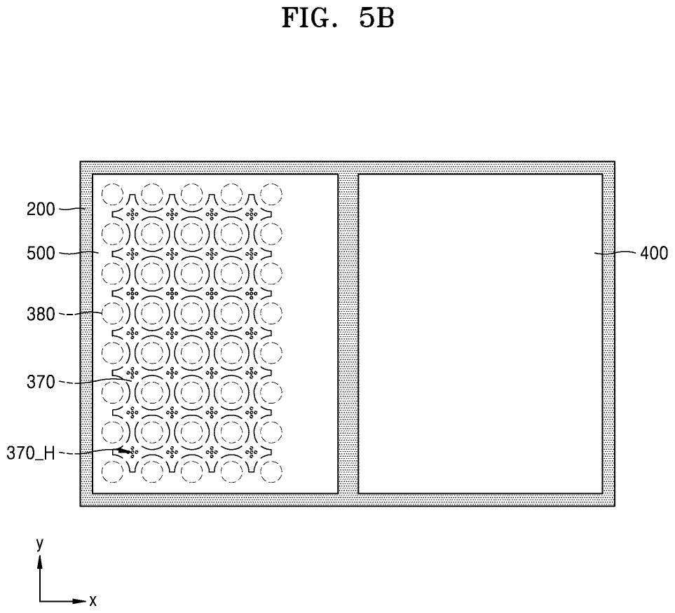

In an embodiment of the present inventive concept, the first underfill material layer 340 of FIG. 2A may be omitted, and the molding member 390 may fill a gap between the first chip 300 and the first redistribution structure 100 and may at least partially surround side walls of the first bump 350. FIGS. 4A to 4C are cross-sectional views showing the structure of a memory device of the semiconductor package 10 of FIG. 2A in more detail.

Referring to FIG. 4A, the second chip 500 may include one memory chip. The memory chip may include, for example, non-volatile memory devices such as DRAM, SRAM, etc., or volatile memory devices such as flash memory. In the semiconductor package 10 according to an embodiment of the present inventive concept, the memory chip of the second chip 500 may include, for example, a DRAM chip. The second chip 500 may be mounted on the second redistribution structure 200 through the second bump 550 to form a flip-chip bonding structure. The second bump 550 may include a filler and solder or only solder, and a plurality of second bumps 550 may be provided.

Referring to FIG. 4B, a second chip 500a may include a semiconductor package having a wire bonding structure. Particularly, the second chip 500a may include a package substrate 510 and a plurality of memory chips 520 stacked on the package substrate 510. The memory chip 520 may be mounted on the package substrate 510 by using an adhesive layer 525 and a wire 530 to form a wire bonding structure. The memory chip 520 of the second chip 500a may include, for example, a volatile memory device such as DRAM, SRAM, etc. or a non-volatile memory device such as flash memory. In the semiconductor package 10 according to an embodiment of the present inventive concept, the memory chip 520 of the second chip 500a may include, for example, a DRAM chip. In addition, the second chip 500a may include an internal sealing material that seals the memory chip 520 and the wire 530 on the package substrate 510. However, in FIG. 4B, the internal sealing material is omitted for convenience.

In FIG. 4B, four memory chips 520 are stacked on the package substrate 510, but the number of memory chips 520 is not limited to four. For example, three or less, or five or more memory chips 520 may be stacked on the package substrate 510. In addition, the memory chip 520 is not limited to a staircase structure, and for example, the memory chips 520 may be stacked on the package substrate 510 to form a zigzag structure or a complex structure of zigzag and staircase structures. The second chip 500a of the package structure may also be mounted on the second redistribution structure 200 through the second bump 550.

Referring to FIG. 4C, a second chip 500b may include a high bandwidth memory (HBM) package. Particularly, the second chip 500b may include a base chip 510a, a plurality of core chips 520a stacked on the base chip 510a, and an internal sealing material 540. In addition, each of the base chip 510a and the core chips 520a may include a through electrode 530a therein. In addition, the top core chip 520a of the core chips 520a might not include the through electrode 530a.

The base chip 510a may include logic elements. Accordingly, the base chip 510a may be a logic chip. The base chip 510a may be disposed below the core chips 520a, integrate signals of the core chips 520a and transmit the signals to the outside, and transmit signals and power from the outside to the core chips 520a. Accordingly, the base chip 510a may be referred to as a buffer chip or a control chip. In addition, each core chip 520a may be a memory chip. For example, each core chip 520a may be a DRAM chip. In addition, the core chip 520a may be stacked on the base chip 510a or a lower core chip 520a through pad-to-pad bonding, hybrid bonding (HB), bonding using a connection terminal, or bonding using an anisotropic conductive film (ACF). In FIG. 4C, four core chips 520a are stacked on the base chip 510a, but the number of core chips 520a is not limited to four. For example, three or less or five or more core chips 520a may be stacked on the base chip 510a.

The second bump 550 may be disposed on the lower surface of the base chip 510a. Thus, the second chip 500b of the HBM package may also be mounted on the second redistribution structure 200 through the second bump 550. The core chips 520a on the base chip 510a may be sealed by the internal sealing material 540. In addition, the upper surface of the top core chip 520a of the core chips 520a might not be covered by the internal sealing material 540. However, in some embodiments of the present inventive concept, the upper surface of the top core chip 520a may be covered by the internal sealing material 540.

FIGS. 5A and 5B are plan views of the semiconductor package according to an embodiment of the present inventive concept. Hereinafter, since components of FIGS. 5A and 5B having the same reference numbers as those of FIGS. 1 to 3 refer to substantially the same components, repeated descriptions thereof are omitted and differences are mainly described.

Referring to FIG. 5A, as in the embodiment of FIG. 1 wherein a plurality of support structures 370 are provided, the support structure 370 may be integrally formed. In an embodiment of the present inventive concept, the support structure 370 may be of a plate type in which the support structures 370 of FIG. 1 are connected to each other. The support structure 370 of a plate-type may surround at least one conductive pillar 380. The semiconductor package 10 according to an embodiment of the present inventive concept may include a plate type support structure 370 surrounding the conductive pillar 380, thereby reducing asymmetric warpage.

In other words, the support structure 370 may have a mesh shape in which an opening OP or a plurality of openings OP is defined. The area of the opening OP in a plan view may be greater than the area of the conductive pillar 380. The conductive pillar 380 may be disposed inside the opening OP. In addition, the openings OP may ensure that the conductive pillars 380 remain electrically isolated from each other while allowing the support structure 370 to provide increased mechanical stability. As shown in FIG. 5A, a distance between the inner surface of the support structure 370 defining the opening OP to the side surface of the conductive pillar 380 may be constant. The conductive pillar 380 and the support structure 370 may be disposed alternately along the third direction (e.g., the diagonal direction) crossing the first horizontal direction (the X-axis direction) and the second horizontal direction (the Y-axis direction). For example, portions of the integrated support structure 370 may be alternately arranged with the conductive pillars 380 along the third direction.

Referring to FIG. 5B, the support structure 370 may further include a through hole 370_H. The size of the through hole 370_H in a plan view may be less than the size of the conductive pillar 380. The semiconductor package 10 may include the through hole 370_H resulting from removing the support structure 370 in the vertical direction (the Z-axis direction), thereby facilitating a process of forming the support structure 370.

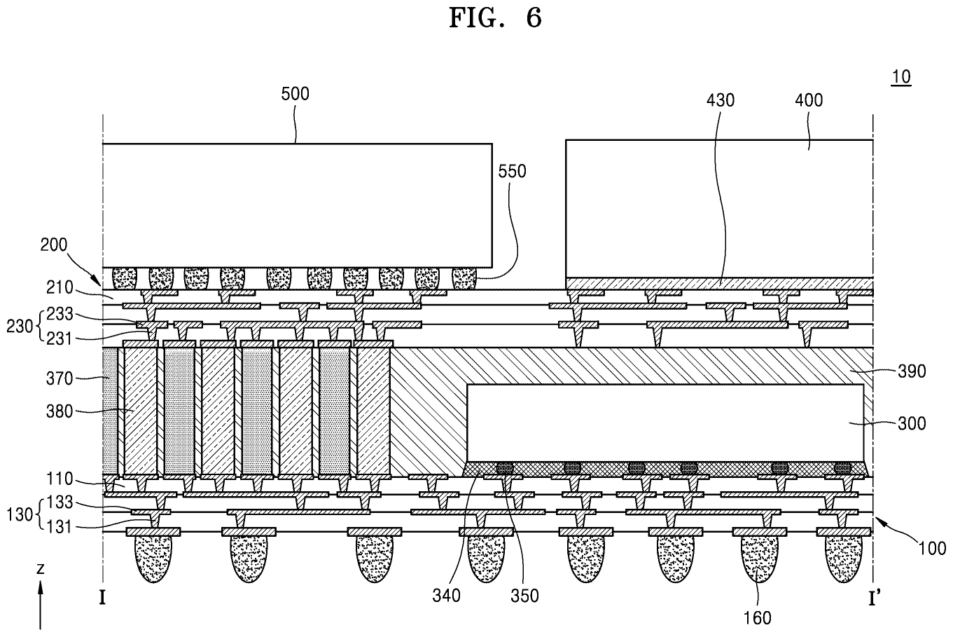

FIG. 6 is a cross-sectional view of a semiconductor package according to an embodiment of the present inventive concept. Hereinafter, since components of FIG. 6 having the same reference numbers as those of FIG. 2A refer to substantially the same components, repeated descriptions thereof are omitted and differences are mainly described.

Referring to FIG. 6, the support structure 370 is disposed between the first redistribution structure 100 and the second redistribution structure 200 and may be connected to the first redistribution structure 100 and/or the second redistribution structure 200. For example, the support structure 370 may contact the first redistribution pattern 130 of the first redistribution structure 100 and the second redistribution pattern 230 of the second redistribution structure 200. The support structure 370 may electrically connect the first redistribution pattern 130 of the first redistribution structure 100 to the second redistribution pattern 230 of the second redistribution structure 200. Accordingly, the power signal transmission characteristics of the semiconductor package 10 may be improved. As described above, the conductive pillar (the support structure 370) may transmit power signals from an external device to the second chip 500, and may, for example, set the support structure 370 as ground.

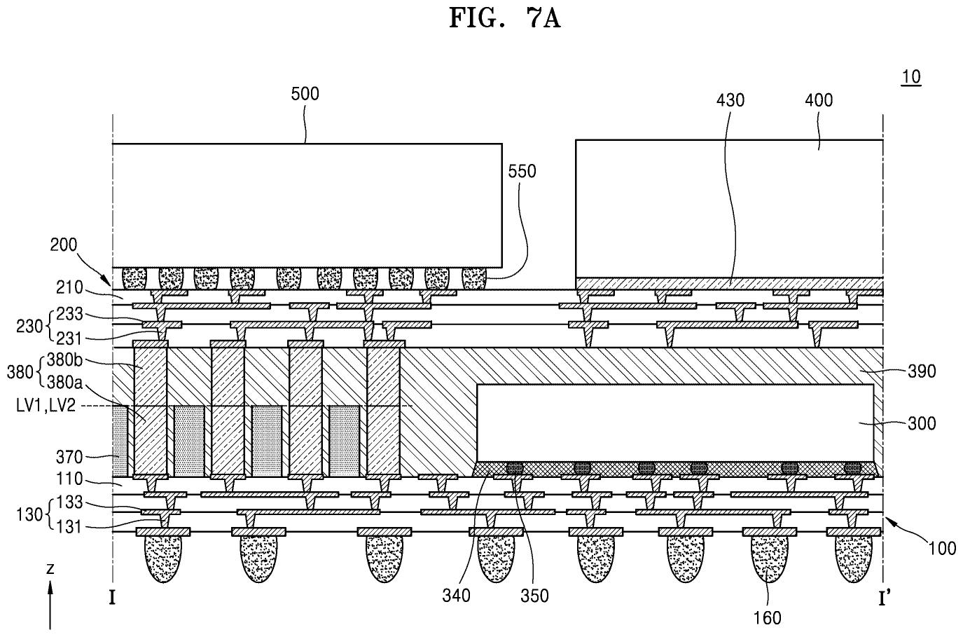

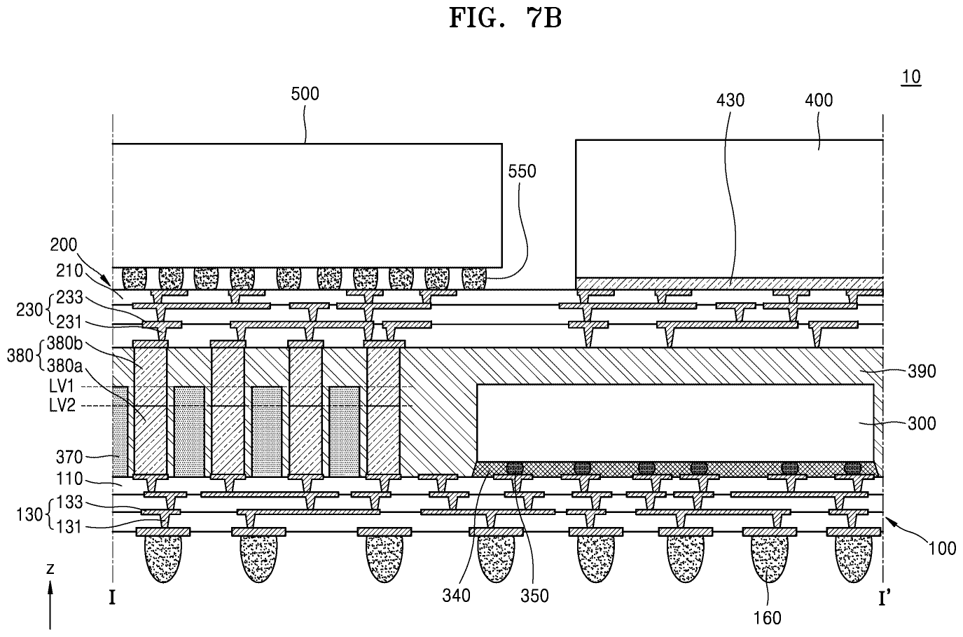

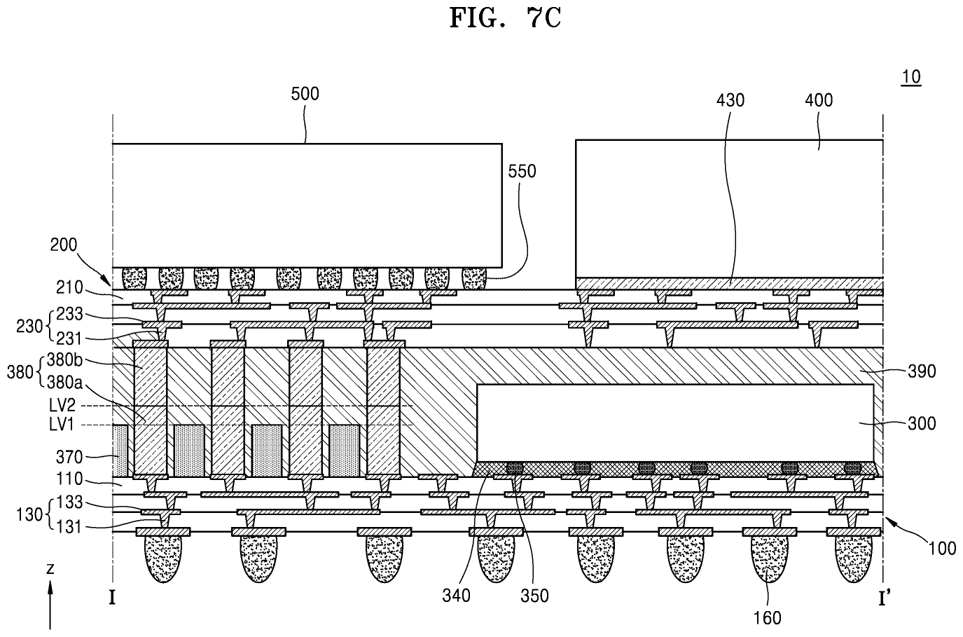

FIGS. 7A to 7C are plan views of a semiconductor package according to an embodiment of the present inventive concept. Since components of FIGS. 7A to 7C having the same reference numbers as those of FIG. 2A refer to substantially the same components, repeated descriptions thereof are omitted and differences are mainly described.

Referring to FIGS. 7A to 7C, in the semiconductor package 10 according to some embodiments of the present inventive concept, the conductive pillar 380 may include a first portion 380a and a second portion 380b stacked on the first portion 380a in the vertical direction (the Z-axis direction). The upper surface of the first portion 380a may be in contact with the lower surface of the second portion 380b. In an embodiment of the present inventive concept, the conductive pillar 380 may be formed by forming the first portion 380a together with the support structure 370 which then undergo a surface cut process, and subsequently forming the second portion 380b. Accordingly, the shape of a grain included in the first portion 380a may be different from the shape of a grain contained in the second portion 380b. For example, the size/boundary of the grain included in the first portion 380a and the size/boundary of the grain included in the second portion 380b may show different aspects. In this regard, by forming the conductive pillar 380 in two steps, the molding member 390 may be easily disposed between the support structure 370 and the conductive pillar 380.

In some embodiments of the present inventive concept, the height of the support structure 370 included in the semiconductor package 10 may be equal to or less than the height of the conductive pillar 380. For example, as shown in FIG. 7A, a vertical level LV1 of the upper surface of the support structure 370 may be the same as a vertical level LV2 of the upper surface of the first portion 380a. As shown in FIG. 7B, the vertical level LV1 of the upper surface of the support structure 370 may be greater than the vertical level LV2 of the upper surface of the first portion 380a. As shown in FIG. 7C, the vertical level LV1 of the upper surface of the support structure 370 may be less than the vertical level LV2 of the upper surface of the first portion 380a. This variability in the vertical level of the support structure 370 relative to the conductive pillar 380 may allow for greater design flexibility in increasing the mechanical and electrical performance of the semiconductor package 10.

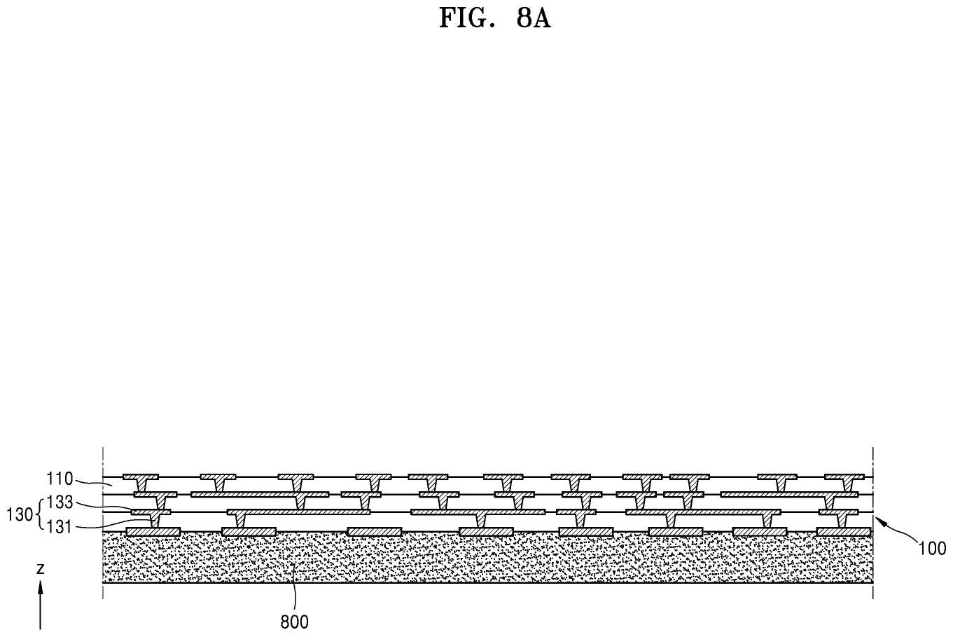

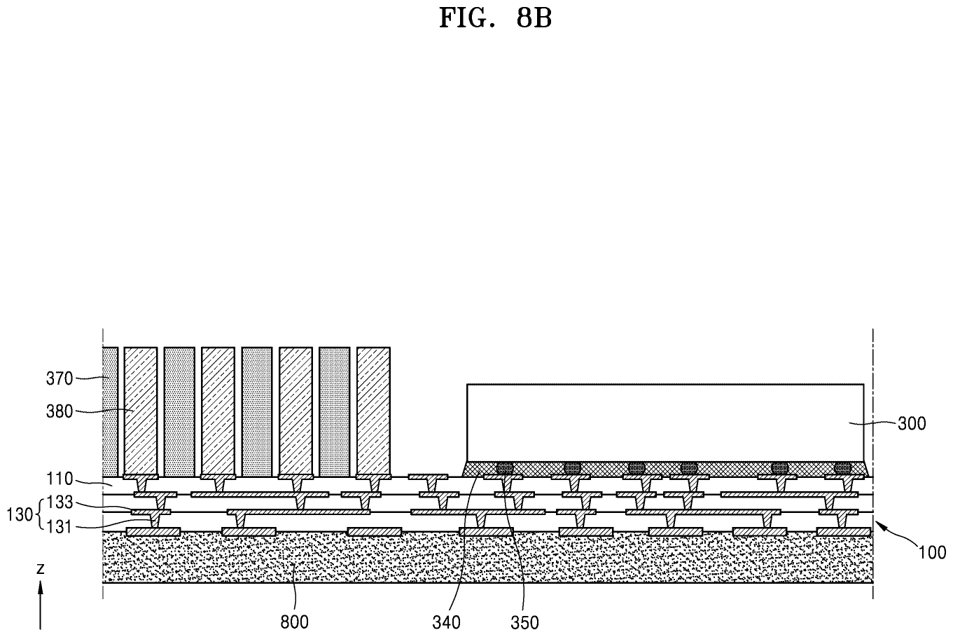

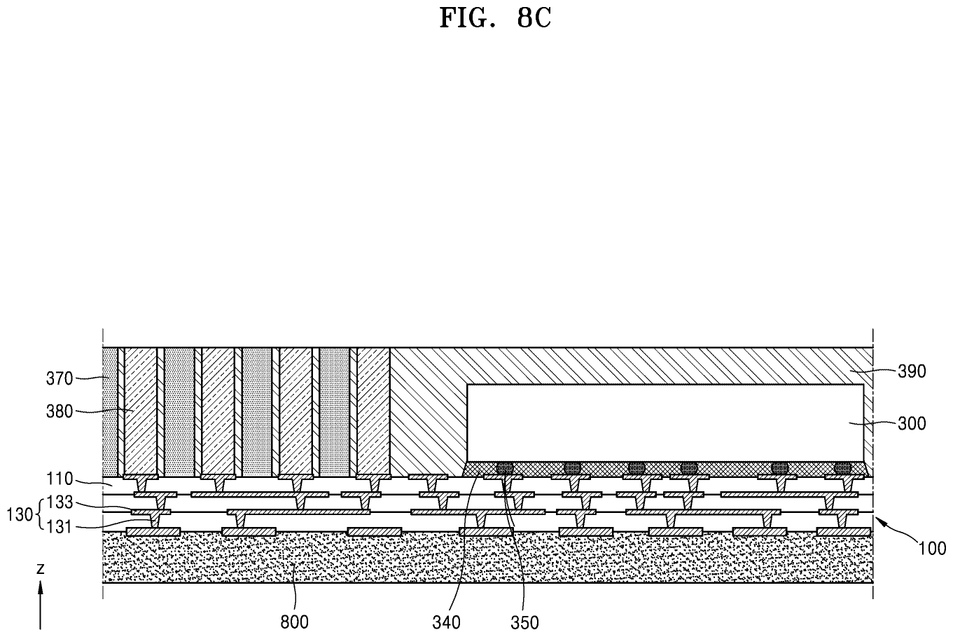

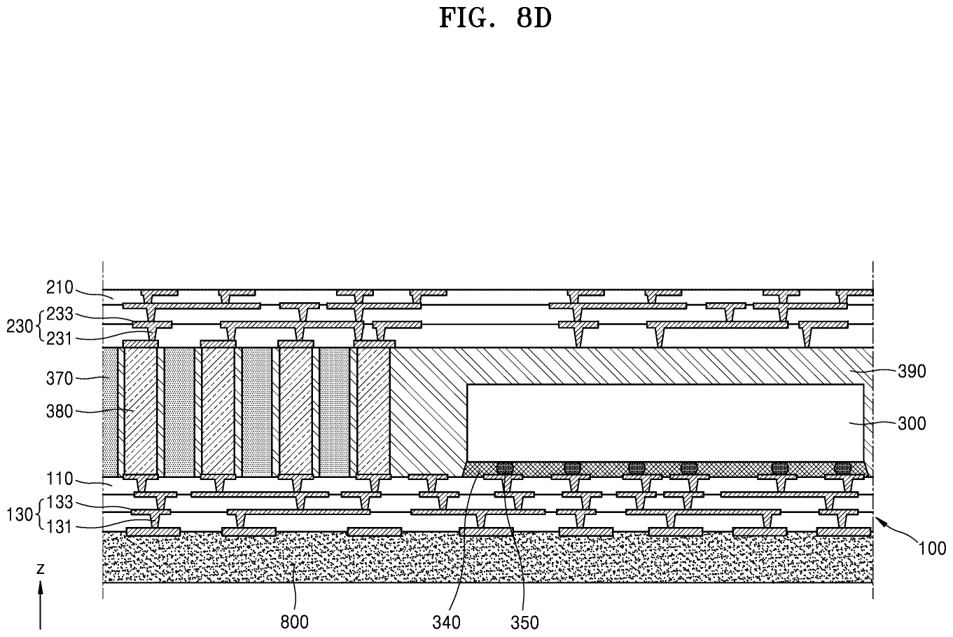

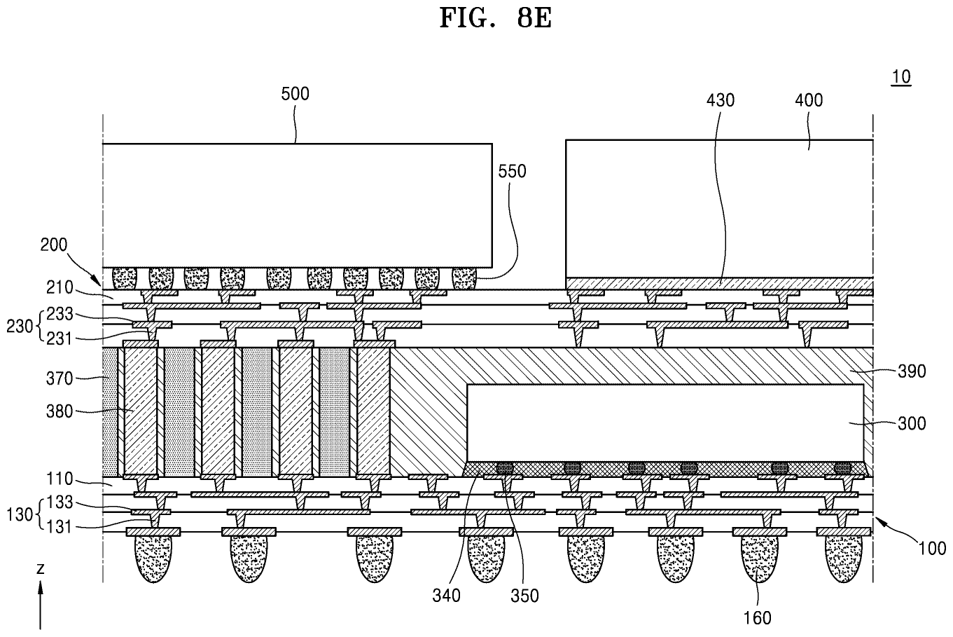

FIGS. 8A to 8E are cross-sectional views illustrating a method of manufacturing a semiconductor package, according to an embodiment of the present inventive concept. Hereinafter, descriptions that are substantially the same as those of FIG. 2A are omitted.

Referring to FIG. 8A, the first redistribution structure 100 is formed on a carrier substrate 800. The carrier substrate 800 may be a large circular substrate, such as a wafer. In some embodiments of the present inventive concept, a PSPI film may be applied onto the carrier substrate 800 to form the first redistribution insulating layer 110. Subsequently, the first redistribution insulating layer 110 may be etched in consistence with the pattern to form an opening, and then a metal may be filled in the opening to form the first redistribution pattern 130. In some embodiments of the present inventive concept, a plurality of first redistribution insulating layers 110 may be provided.

Referring to FIG. 8B, the conductive pillar 380 and the support structure 370 may be formed on the first redistribution structure 100, and the first chip 300 may be mounted on the first redistribution structure 100 such that the first chip 300 is apart from the conductive pillar 380 and the support structure 370 in the first horizontal direction (the X-axis direction). Each of the conductive pillar 380 and the first chip 300 may be physically connected to the first redistribution pattern 130. In an embodiment of the present inventive concept, the support structure 370 may be physically connected to the first redistribution pattern 130.

In some embodiments of the present inventive concept, the conductive pillar 380 and the support structure 370 may be formed by an electroplating process using the seed metal formed on the first redistribution structure 100. In some embodiments of the present inventive concept, the seed metal may include Cu, Ti, Ta, TiN, TaN, and the like.

First, a photoresist (PR) is coated on the seed metal and developed after being subjected to an exposure process. Subsequently, the conductive pillar 380 and the support structure 370 extending in the vertical direction (the Z-axis direction) may be formed through a plating process. A PR pattern is removed after the conductive pillar 380 and the support structure 370 are formed. The PR pattern may be removed through a strip/ashing process. After the PR pattern is removed, the seed metal may be exposed between the conductive pillar 380 and the support structure 370. The exposed seed metal may be removed through an etching process. The upper surface of the first redistribution structure 100 may be exposed by removing the seed metal. The seed metal on the lower surface of the conductive pillar 380 and the support structure 370 may be maintained as is.

When the conductive pillar 380 is formed in two steps as in FIGS. 7A to 7C, the first portion 380a is formed by a plating process and is subjected to a surface cut process and repeated coating with PR, exposure to light, developing, removing of the PR pattern therefrom, and etching of the exposed seed metal to thereby form the second portion 380b.

The first chip 300 may be mounted on the first redistribution structure 100 through a flip-chip method. However, embodiments of the present inventive concept are not limited thereto, and a pad of the first chip 300 may be coupled to a pattern of the first redistribution structure 100 through direct bonding such that the first chip 300 is mounted on the first redistribution structure 100.

Referring to FIG. 8C, the molding member 390 covering the conductive pillar 380 and the first chip 300 is formed, and the molding member 390 is ground such that the upper surface of the conductive pillar 380 is exposed in the vertical direction (the Z-axis direction). In some embodiments of the present inventive concept, the upper surface of the support structure 370 may be exposed or covered by the molding member 390 in the same manner as the conductive pillar 380.

Referring to FIGS. 8D and 8E, the second redistribution structure 200 may be disposed on the upper surface of the molding member 390. Then, the second chip 500 and the heat dissipation chip 400 may be disposed on the upper surface of the second redistribution structure 200. The second chip 500 may be mounted on a position overlapping the support structure 370 and the conductive pillar 380 in the vertical direction (the Z-axis direction), and the heat dissipation chip 400 may be mounted on a position overlapping the first chip 300 in the vertical direction (the Z-axis direction). Subsequently, the semiconductor package 10 may be manufactured by removing the carrier substrate 800 and forming the external connection terminal 160 on the lower surface of the first redistribution structure 100.

While the present inventive concept has been described with reference to embodiments thereof, it will be understood by those of ordinary skill in the art that various changes in form and details may be made thereto without departing from the spirit and scope of the present inventive concept.

1. A semiconductor package comprising:
a first redistribution structure;
a first chip disposed on the first redistribution structure;
a molding member at least partially surrounding the first chip and disposed on the first redistribution structure;
a plurality of conductive pillars penetrating the molding member in a vertical direction;
a support structure disposed between adjacent conductive pillars of the plurality of conductive pillars and disposed on the first redistribution structure;
a second redistribution structure disposed on the molding member, the plurality of conductive pillars, and the support structure;
a second chip disposed on the second redistribution structure and overlapping the plurality of conductive pillars; and
a heat dissipation chip overlapping the first chip in the vertical direction.

2. The semiconductor package of claim 1, wherein, in a plan view, a shape of each of the plurality of conductive pillars is different from a shape of the support structure.

3. The semiconductor package of claim 1, wherein the support structure overlaps the second chip in the vertical direction.

4. The semiconductor package of claim 1, wherein the support structure penetrates the molding member in the vertical direction.

5. The semiconductor package of claim 1, wherein:
a vertical level of an upper surface of the support structure is less than a vertical level of an upper surface of each of the plurality of conductive pillars.

6. The semiconductor package claim 5, wherein the molding member is in contact with the upper surface of the support structure.

7. The semiconductor package of claim 1, wherein:
each of the plurality of conductive pillars comprises a first portion and a second portion stacked on the first portion in the vertical direction, and
a shape of a grain that is included in the first portion is different from a shape of a grain that is included in the second portion.

8. The semiconductor package of claim 1, wherein:
the second redistribution structure comprises a second redistribution pattern, and
the support structure is in contact with the second redistribution pattern.

9. The semiconductor package of claim 1,
wherein the support structure is of a plurality of support structures, and the plurality of support structures is arranged along a first horizontal direction and a second horizontal direction that is substantially perpendicular to the first horizontal direction.

10. The semiconductor package of claim 9, wherein:
the support structure and the plurality of conductive pillars are alternately arranged in a third horizontal direction crossing the first horizontal direction and the second horizontal direction.

11. The semiconductor package of claim 1, wherein the support structure is of a plurality of support structures, and wherein the plurality of support structure surrounds at least one conductive pillar of the plurality of conductive pillars.

12. The semiconductor package of claim 11, wherein: the support structure comprises a through hole smaller than the conductive pillar.

13. A semiconductor package comprising:
a first redistribution structure;
a first chip disposed on the first redistribution structure;
a molding member at least partially surrounding the first chip and disposed on the first redistribution structure;
a conductive pillar penetrating the molding member in a vertical direction;
a support structure adjacent to the first chip in a first horizontal direction and disposed on the first redistribution structure, wherein the support structure is spaced apart from the conductive pillar;
a second redistribution structure disposed on the molding member, the conductive pillar, and the support structure; and
a second chip disposed on the second redistribution structure and overlapping at least a portion of the conductive pillar and at least a portion of the support structure,
wherein a shape of an upper surface of the support structure is different from a shape of an upper surface of the conductive pillar.

14. The semiconductor package of claim 13, wherein,
in a plan view, a center of the support structure is identical to a center of a virtual square formed by connecting centers of four adjacent conductive pillars.

15. The semiconductor package of claim 13, wherein:
the support structure has a mesh shape in which an opening is defined, and
the conductive pillar is disposed in the opening.

16. The semiconductor package of claim 13, wherein:
a vertical level of the upper surface of the support structure is equal to or less than a vertical level of the upper surface of the conductive pillar.

17. The semiconductor package of claim 13, wherein:
the molding member is disposed between the support structure and the conductive pillar.

18. The semiconductor package of claim 13, further comprising:
a heat dissipation chip overlapping the first chip and disposed on the second redistribution structure.

19. The semiconductor package of claim 13, wherein the support structure is electrically connected to the second redistribution structure.

20. A semiconductor package comprising:
a first redistribution structure;
a first chip disposed on the first redistribution structure;
a molding member sealing the first chip;
a plurality of conductive pillars penetrating the molding member and arranged in a first horizontal direction and a second horizontal direction that is substantially perpendicular to the first horizontal direction in a plan view;
a support structure disposed between adjacent conductive pillars of the plurality of conductive pillars with a predetermined distance from each of the adjacent conductive pillar and having a height equal to or less than a height of each of the plurality of conductive pillars;
a second redistribution structure disposed on the molding member;
a second chip disposed on the second redistribution structure and overlapping the plurality of conductive pillars and the support structure; and
a heat dissipation chip overlapping the first chip,
wherein the plurality of conductive pillars and the support structure are alternately disposed along a third direction that crosses the first horizontal direction and the second horizontal direction.

21. (canceled)

22. (canceled)

23. (canceled)

24. (canceled)
